(19) United States
(12) Patent Application Publication
(10) Pub. No.: US 2010/0318874 A1
(43) Pub. Date: Dec. 16, 2010

(54) ELECTRONIC MEMORY DEVICE AND METHOD FOR ERROR CORRECTING THEREOF

(75) Inventors: Shih-Fang Hung, Chung Ho City (TW); Tzu-Wei Fang, Chung Ho City (TW); Hsiang-An Hsieh, Chung Ho City (TW)

Correspondence Address: Flash Intellectual Property, Inc.;Attn. Cheng-Ju Chiang, P.O. Box 766, Chino, CA, 91708, US

(73) Assignee: A-DATA TECHNOLOGY (SUZHOU) CO., LTD., Suzhou (CN)

(21) Appl. No.: 12/649,799

(22) Filed: Dec. 30, 2009

(30) Foreign Application Priority Data
Jun. 12, 2009 (CN) 200910032406.7

(51) Int. Cl. H03M 13/05; G06F 11/10

(52) U.S. Cl. 714/752; 714/E11.032

(57) ABSTRACT

An electronic memory device includes a controller and a memory unit. The controller includes a micro processor, a host interface, a memory unit interface connected to the memory unit, a data cache area for provisionally storing data, an ECC unit coupled to the memory unit for testing whether there is any error bit in the data or not, and an error correcting unit coupled to the memory unit. If an error bit in the data is found and can be dealt by the ECC unit, the error bit is then directly recovered by the ECC unit. However, if the error bit exceeds beyond the processing capability of the ECC unit, the error correcting unit is selected to primarily invert predetermined data bit till the number of the error can be successfully recovered by the ECC unit.

### BACKGROUND OF THE INVENTION

1. Field of the Invention

The present invention relates to electronic memory devices and methods for error correcting thereof, and more particularly to non-volatile electronic memory devices and methods for error correcting of such non-volatile electronic memory devices.

2. Description of Related Art

Electronic memory devices can be roughly classified into volatile and nonvolatile ones. Volatile memory devices allow high speed read and write operations, but lose data when disconnected from an external power source. On the other hand, nonvolatile memory devices retain stored information even when disconnected from an external power source.

NAND-type flash memories are one of common forms of the nonvolatile memory devices. Because of their high speed of read and write, power save and high reliabilities, the NAND-type flash memories are widely used in consumer electronics products as data storages. NAND-type MLC (Multi-Level Cell) flash memories are improvements of the NAND-type flash memories with larger storage capabilities and lower cost.

In burning process, two record bits of a same memory unit structure two memory pages of a same memory area. The two memory pages include a low word which is called LSB (Least Significant Bit) page and a high word which is called MSB (Most Significant Bit) page, respectively. Although the LSB page and the MSB page are different memory pages, they essentially belong to the same memory unit and they are so-called “Paired Pages”.

FIG. 1 is a prior art schematic diagram showing burning processes of conventional MLC-type LSB page and MSB page. The detailed steps are as follows:
(1). If the low word is “1” (the status of the LSB page after burning process is “U”) and the high word is “1” as well, the memory unit remains the status “U”
(2). If the low word is “1” (the status of the LSB page after burning process is “U”) and the high word is “0”, the memory unit changes from the status “U” to a new status “C”;
(3). If the low word is “0” (the status of the LSB page after burning process is “A”) and the high word is “1”, the memory unit remains the status “A”; and
(4). If the low word is “0” (the status of the LSB page after burning process is “A”) and the high word is “0” as well, the memory unit changes from the status “A” to a new status “B”.

Usually, in a read/write data process of the flash memory, an ECC (Error Correction Code) is used for ensuring correctness in the process. Especially in the high density flash memory chip, much stronger error checking and correcting capabilities are needed. It is an industry problem that no flash memory provider can guarantee the all the memory cells of the flash memory are in good conditions. Besides, the memory cells may be broken or age after long time usage, or may occur errors in read/write data process. Under these conditions, most of the controller providers are requested with suitable ECC processes which are applied in the flash memory in order to ensure correctly read/write thereof. Once the errors are found, they will be recovered by the ECC processes. However, if the number of the errors are large and exceed beyond the processing capabilities of the ECC processes, such errors can't be recovered by the ECC processes, which may result in damage of the flash memory. The conventional method to overcome this shortage is to enhance processing capabilities of the ECC processes. However, such solution may occupy many redundant bits which are difficultly provided by the flash memory.

Hence, an improved electronic memory device and its error correcting method are needed to solve the problems above.

### BRIEF SUMMARY OF THE INVENTION

The present invention discloses an electronic memory device including a controller and a memory unit made up of flash memory cells. The controller includes a micro processor for processing control commands and for managing data transmission, a host interface for being connected to the host device, a memory unit interface connected to the memory unit, a data cache area for provisionally storing data received from the host interface or the memory unit interface, an ECC (Error Correction Code) unit coupled to the memory unit in order to test whether there is any error bit in the data or not, and an error correcting unit coupled to the memory unit. If an error bit in the data is found and can be dealt with under the processing capability of the ECC unit, the error bit is directly recovered by the ECC unit. However, if the error bit exceeds beyond the processing capability of the ECC unit, the error correcting unit is selected to primarily invert predetermined data bit in a inversion process till the number of the error can be successfully recovered by the ECC unit.

A method for correcting an electronic memory device includes steps of: a) providing the above-mentioned electronic memory device; b) testing whether there is any error bit in the data or not; and c1) if an error bit in the data being found and can be dealt with under the processing capability of the ECC unit, the error bit being directly recovered by the ECC unit; or c2) if the error bit exceeding beyond the processing capability of the ECC unit, the error correcting unit being selected to primarily invert predetermined data bit in a inversion process; after each inversion process, a test being made whether the number of the error can be processed by the ECC, further inverting predetermined data bit till the number of the error can be directly recovered by the ECC unit.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a prior art schematic diagram showing burning processes of conventional MLC-type LSB page and MSB page;

FIG. 2 is a block diagram showing essential parts of an electronic memory device according to a preferred embodiment of the present invention;

FIG. 3 is a diagram showing a first method for error checking and correcting according to the preferred embodiment of the present invention;

FIGS. 4A and 4B are diagrams showing a second method for error checking and correcting according to the preferred embodiment of the present invention; and

FIG. 5 is a diagram showing a third method for error checking and correcting according to the preferred embodiment of the present invention.

### DETAILED DESCRIPTION OF THE PREFERRED EMBODIMENT

In the following description, numerous specific details are set forth to provide a thorough understanding of the present invention. However, it will be obvious to those skilled in the art that the present invention may be practiced without such specific details. In other instances, well-known circuits have been shown in block diagram form in order not to obscure the present invention in unnecessary detail. For the most part, details concerning timing considerations and the like have been omitted inasmuch as such details are not necessary to obtain a complete understanding of the present invention and are within the skills of persons of ordinary skill in the relevant art.

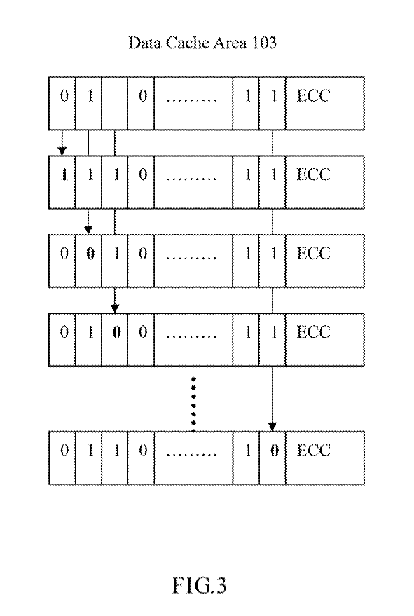

Referring to FIG. 2, an electronic memory device 1 including a controller 10 and a memory unit 11 is disclosed according to an embodiment of the present invention. The electronic memory device can be used for data transmission with a host device.

The controller 10 includes a micro processor 101, an ECC unit 102, a data cache area 103, a host interface 104, a memory unit interface 105 and an error correcting unit 106. The micro processor 101 is adapted for processing control commands between the units within the controller 10, and is also adapted for managing data transmission. The host interface 104 is adapted for being connected to peripheral devices for transmitting commands and data. The memory unit interface 105 is connected to the memory unit 11 for data transmission therebetween. The data cache area 103 is adapted for provisionally storing data received from the host interface 104 and the memory unit interface 105. The ECC unit 102 is coupled to the memory unit 11 for an error checking function. If an error bit in data is found, the ECC unit 102 is primarily selected to recover this error bit. If the error bit exceeds beyond the processing capability of the ECC unit 102 so as can't be recovered by the ECC unit 102, the error correcting unit 106 is then selected to deal with such error via inverting predetermined data bit.

When data is written into the electronic memory device 1, the host interface 104 of the controller 10 is used to receive peripheral data which is provisionally stored in the data cache area 103. The data stored in the data cache area 103 is added with error correcting code by the ECC unit 102 and is then transferred to the memory unit 11 via the memory unit interface 105.

When the data is readout from the memory unit 11, the memory unit interface 105 of the memory unit 11 is selected. The readout data is provisionally stored in the data cache area 103. The ECC unit 102 tests whether there is any error in the readout data or not. If an error is found and the error can be recovered by the ECC unit 102, the data is recovered by the ECC unit 102 accordingly and then is outputted via the host interface 104. However, if the error exceeds beyond processing capability of the ECC unit 102 so as not to be recovered by the ECC unit 102, the error correcting unit 106 is then selected to inverting predetermined data bit to decrease the error bit in the data. After such process, the error in the data returns to a level which can be successfully processed by the ECC unit 102. As a result, the error can be recovered.

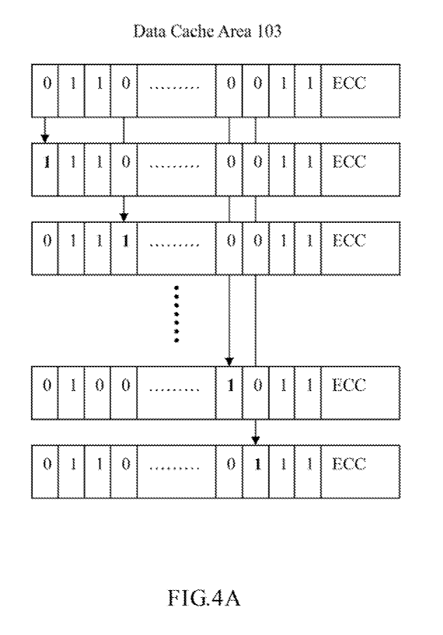

FIG. 3 shows a first method for error checking and correcting according to the preferred embodiment of the present invention. Take a 512-bit data for example, if the 512-bit data provisionally stored in the data cache area 103 occurs some errors which exceed beyond processing capabilities of the ECC unit 102, the error correcting unit 106 is then selected inverting predetermined data bit to decrease the error bit in the 512-bit data. After each inversion process, a test is made till the errors decrease to the level which can be recovered by the ECC unit 102. The recovered 512-bit data is then outputted through the host interface 104 after being successfully recovered by the ECC unit 102.

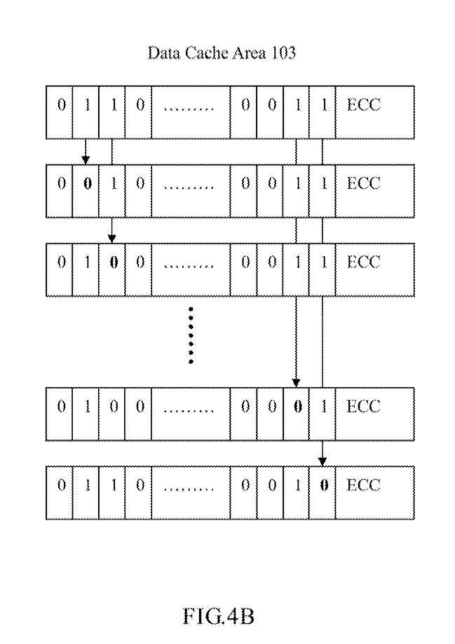

In order to short the recovery time, a second method for error checking and correcting is disclosed in FIGS. 4A and 4B. In the second method, only the data bit “0” is inverted in spite of the data bit “1”, or only the data bit “1” is inverted in spite of the data bit “0”, which is determined by the user.

Referring to FIG. 4A, take a 512-bit data for example, if the 512-bit data provisionally stored in the data cache area 103 occurs some errors which exceed beyond processing capabilities of the ECC unit 102, the error correcting unit 106 is then selected inverting only data bit “0” in the 512-bit data in order to decrease error numbers. After each inversion process, a test is made whether the remain error numbers can be recovered by the ECC unit 102 or not. When the error numbers reach a level which can be successfully recovered by the ECC unit 102, the recovered 512-bit data is then outputted through the host interface 104.

Referring to FIG. 4B, take a 512-bit data for example, if the 512-bit data provisionally stored in the data cache area 103 occurs some errors which exceed beyond processing capabilities of the ECC unit 102, the error correcting unit 106 is then selected inverting only data bit “1” in the 512-bit data in order to decrease error numbers. After each inversion process, a test is made whether the remain error numbers can be recovered by the ECC unit 102 or not. When the error numbers reach a level which can be successfully recovered by the ECC unit 102, the recovered 512-bit data is then outputted through the host interface 104.

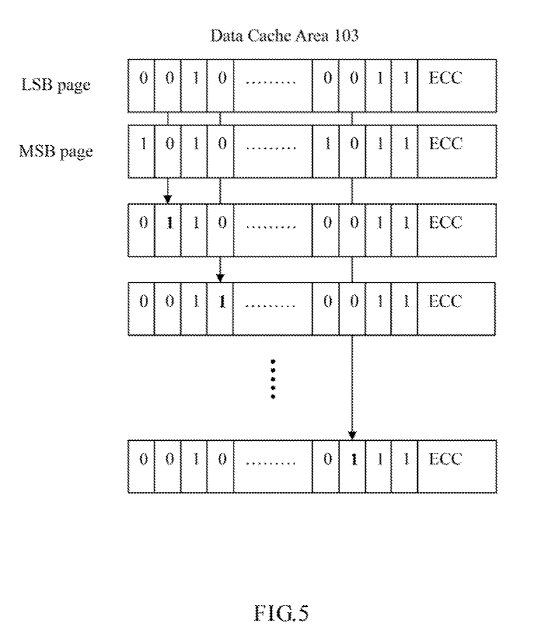

In order to further shorten the recovery time, a third method for error checking and correcting is disclosed in FIG. 5. In the third method, the data patterns which easily occur errors are primarily selected for inversion process.

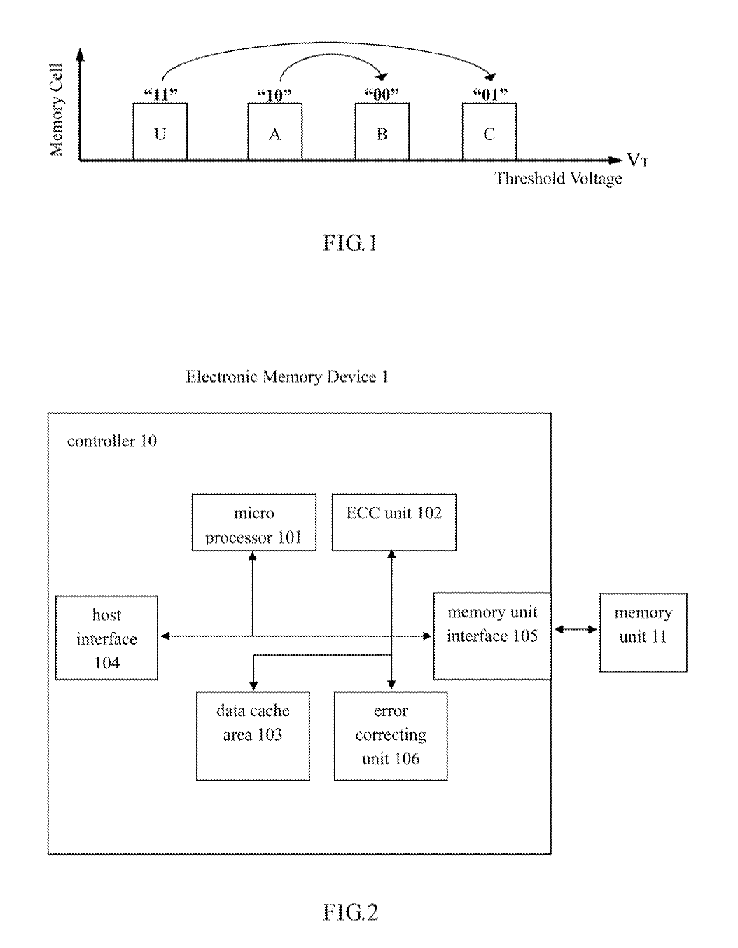

As shown in FIG. 1, when the memory unit of the MSB page is burned from status “U” to status “C”, the value of the memory unit changes from “11” to “01” and the memory unit must pass two middle status “A” and “B”. Because of the special electrical characteristic, such burning process with multiple statuses may easily occur a condition where the memory unit does not be burned accurately. For example, the memory unit is burned to status “B” instead of status “C”, which may result in error data.

Referring to FIG. 5, the third method is designed for overcoming the problem above. In the third method, the data patterns of the data cache area 103 easily occurring errors are primarily dealt with by the error correcting unit 106 in inversion process. If the data of LSB page stored in the data cache area 103 occurs some errors which exceed beyond processing capabilities of the ECC unit 102, the MSB page corresponding to the LSB page is selected to be stored in the data cache area 103 by the controller 10. Comparing the LSB page with the MSB page, those corresponding bits with the same data bit “0” are recognized as the data patterns which easily occur errors. Such data bit “0” labeled by the arrow shown in FIG. 5 is then selected inverting predetermined data bit. After each inversion process, a detection is made whether the errors decrease to the level which can be recovered by the ECC unit 102. When the errors reach such level, they are successfully recovered by the ECC unit 102. The recovered 512-bit data is then outputted through the host interface 104. As a result, the recovery time in the third method can be greatly shortened.

Comparing with the prior art, the electronic memory device 1 of the present invention uses processes of inverting predetermined data bit to finally recover the errors in the data. The complexity of the ECC unit 102 can be simplified.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. An electronic memory device for connecting to a host device, comprising:
a memory unit made up of flash memory cells; and
a controller comprising:
a micro processor for processing control commands and managing data transmission;
a host interface for being connected to the host device;
a memory unit interface connected to the memory unit;
a data cache area for provisionally storing data received from the host interface or the memory unit interface;
an ECC (Error Correction Code) unit coupled to the memory unit in order to test whether there is any error bit in the data or not; and
an error correcting unit coupled to the memory unit; wherein
if an error bit in the data is found and can be dealt with under the processing capability of the ECC unit, the error bit is directly recovered by the ECC unit; and wherein
if the error bit exceeds beyond the processing capability of the ECC unit, the error correcting unit is selected to primarily invert predetermined data bit in a inversion process till the number of the error can be successfully recovered by the ECC unit.

2. The electronic memory device according to claim 1, wherein after each inversion process, a test is made whether the number of the error can be processed by the ECC unit.

3. The electronic memory device according to claim 1, wherein the predetermined data bit is “1”.

4. The electronic memory device according to claim 1, wherein the predetermined data bit is “0”.

5. The electronic memory device according to claim 1, wherein the predetermined data bit is what easily occurs errors.

6. The electronic memory device according to claim 5, wherein the data stored in the data cache area comprises a LSB (Least Significant Bit) page and a MSB (Most Significant Bit) page, the bits of the LSB page identical with corresponding bits of the MSB page being recognized as the predetermined data bit which easily occurs errors.

7. The electronic memory device according to claim 6, wherein the corresponding bits “0” of the LSB page and the MSB page are recognized as the predetermined data bit which easily occurs errors.

8. A method for correcting an electronic memory device comprising steps of:
a) providing an electronic memory device which comprises a memory unit and a controller, the controller comprising:
a micro processor for processing control commands and managing data transmission;
a host interface;
a memory unit interface connected to the memory unit;
a data cache area for provisionally storing data received from the host interface or the memory unit interface;
an ECC (Error Correction Code) unit coupled to the memory unit; and
an error correcting unit coupled to the memory unit;
b) testing whether there is any error bit in the data or not; and
c1) if an error bit in the data being found and can be dealt with under the processing capability of the ECC unit, the error bit being directly recovered by the ECC unit;
c2) if the error bit exceeding beyond the processing capability of the ECC unit, the error correcting unit being selected to primarily invert predetermined data bit in a inversion process; after each inversion process, a test being made whether the number of the error can be processed by the ECC, further inverting predetermined data bit till the number of the error can be directly recovered by the ECC unit.

9. The method for correcting the electronic memory device according to claim 8, wherein when the error bit exceeds beyond the processing capability of the ECC unit, the inversion process comprises step of inverting data bit “1”.

10. The method for correcting the electronic memory device according to claim 8, wherein when the error bit exceeds beyond the processing capability of the ECC unit, the inversion process comprises step of inverting data bit “0”.

11. The method for correcting the electronic memory device according to claim 8, wherein when the error bit exceeds beyond the processing capability of the ECC unit, the inversion process comprises step of inverting data bit which easily occurs errors.

12. The method for correcting the electronic memory device according to claim 11, wherein the data stored in the data cache area comprises a LSB (Least Significant Bit) page and a MSB (Most Significant Bit) page, the bits of the LSB page identical with corresponding bits of the MSB page being recognized as the predetermined data bit which easily occurs errors.

13. The method for correcting the electronic memory device according to claim 12, wherein the corresponding bits “0” of the LSB page and the MSB page are recognized as the predetermined data bit which easily occurs errors.
